(19) United States
(12) Patent Application Publication
(10) Pub. No.: US 2018/0375513 A1
(43) Pub. Date: Dec. 27, 2018

(54) Proximity Sensor and Proximity Sensing Module

(71) Applicant: SensorTek technology Corp., HSINCHU COUNTY (TW)

(72) Inventors: Kun-Yang Li, HSINCHU COUNTY (TW); Meng-Yong Lin, HSINCHU COUNTY (TW); Sheng-Chun Chen, HSINCHU COUNTY (TW)

(21) Appl. No.: 15/969,786

(22) Filed: May 3, 2018

Related U.S. Application Data
(60) Provisional application No. 62/500,652, filed on May 3, 2017.

(51) Int. Cl. H03K 17/945; G01S 17/02; H03K 17/968

(52) U.S. Cl. CPC H03K 17/945; G01S 7/4813; H03K 17/968; G01S 17/026

(57) ABSTRACT

A proximity sensor for a non-aperture mechanism includes a control circuit for generating a control signal; a first light-emitting element for emitting a first light source according to the control signal of the control circuit; a second light-emitting element for emitting a second light source according to the control signal of the control circuit; and a light sensing element coupled to the control circuit, for sensing the first light source and the second light source reflected by an object, and determining a distance between the proximity sensor and the object according to light intensities of the reflected first light source and the reflected sensed second light source; wherein the light sensing element and the first light-emitting element have a first distance therebetween, the light sensing element and the second light-emitting element have a second distance therebetween, and the second distance is greater than the first distance.

### CROSS REFERENCE TO RELATED APPLICATION

This application claims the benefit of U.S. Provisional Application No. 62/500,652, filed on May 3, 2017, the contents of which are incorporated herein by reference.

### BACKGROUND OF THE INVENTION

### 1. Field of the Invention

The present invention relates to a proximity sensor and proximity sensing module, and more particularly, to a proximity sensor and proximity sensing module capable of being applied on a non-aperture mechanism.

### 2. Description of the Prior Art

With the advancement and development of smart phones, portable mobile devices or other electronic devices, proximity sensors (PS) and ambient light sensors (ALS) have been widely utilized in the electronic devices to sense a distance between a mobile device and an object or to detect whether the object exists or not, such that the electronic device may automatically adjust a brightness of a display according to the light intensity of the surrounding environment. For example, the proximity sensor may be utilized to sense a face of a user and the distance between the user and the display of the electronic device. Therefore, when the proximity sensor approaches the face of the user, the electronic device may automatically dim the display and turn off a touch function, so as to prevent the user's face from touching the display and hanging up a call.

When the proximity sensor is applied on the electronic device, an aperture on a top surface corresponding to the proximity sensor is needed, which coordinates with a light-emitting diode (LED) and emits light through the aperture, so as to determine the distance with the object according to a light intensity of the light reflected by the object. However, for a perspective of appearance, with the conventional trend of downsizing aperture or non-aperture mechanism of the mobile phones, when the proximity sensor is applied on the display with the non-aperture mechanism, the light emitted by the LED of the proximity sensor is reflected by a cover glass of the display, which significantly increases a crosstalk value of the proximity sensor and affects a sensitivity of the proximity sensor. For example, U.S. Pat. No. 8,581,193, U.S. application No. 20160054175 and China publication No. 102967362 individually have provided the light sensor for the electronic devices to sense the distance between the object and the electronic device, but the problem of the proximity sensor incapable of effectively sensing the distance with the object when utilized on the non-aperture mechanism is not solved.

Therefore, how to solve the problem of the proximity sensor incapable of effectively sensing the distance with the object when utilized on the non-aperture mechanism has become one of the important issues in the industry.

### SUMMARY OF THE INVENTION

To solve the above problems, the present invention provides a proximity sensor and proximity sensing module for the non-aperture mechanisms.

The present invention discloses a proximity sensor for a non-aperture mechanism, comprising a control circuit for generating a control signal; a first light-emitting element coupled to the control circuit, for emitting a first light source according to the control signal of the control circuit; a second light-emitting element coupled to the control circuit, for emitting a second light source according to the control signal of the control circuit; and a light sensing element coupled to the control circuit, for sensing the first light source and the second light source reflected by an object, and determining a distance between the proximity sensor and the object according to light intensities of the reflected first light source and the reflected sensed second light source; wherein the light sensing element and the first light-emitting element have a first distance therebetween, the light sensing element and the second light-emitting element have a second distance therebetween, and the second distance is greater than the first distance.

The present invention further discloses a proximity sensing module, comprising a cover glass; a first masking layer coated on an inner surface of the cover glass, wherein the first masking layer is a non-aperture masking layer; and a proximity sensor for determining a distance with an object by emitting light sources and receiving the reflected light sources, wherein the proximity sensor comprises a control circuit for generating a control signal; a first light-emitting element coupled to the control circuit, for emitting a first light source according to the control signal of the control circuit; a second light-emitting element coupled to the control circuit, for emitting a second light source according to the control signal of the control circuit; and a light sensing element coupled to the control circuit, for sensing the first light source and the second light source reflected by the object, and determining the distance between the proximity sensor and the object according to light intensities of the reflected first light source and the reflected sensed second light source; wherein the light sensing element and the first light-emitting element have a first distance therebetween, the light sensing element and the second light-emitting element have a second distance therebetween, and the second distance is greater than the first distance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a proximity sensing module according to an embodiment of the present invention.

FIG. 2 is a schematic diagram of another proximity sensing module according to an embodiment of the present invention.

FIGS. 3A-3D are circuit diagrams of the proximity sensor according to embodiments of the present invention.

FIGS. 4A-4C are circuit diagrams of the proximity sensor according to embodiments of the present invention.

### DETAILED DESCRIPTION

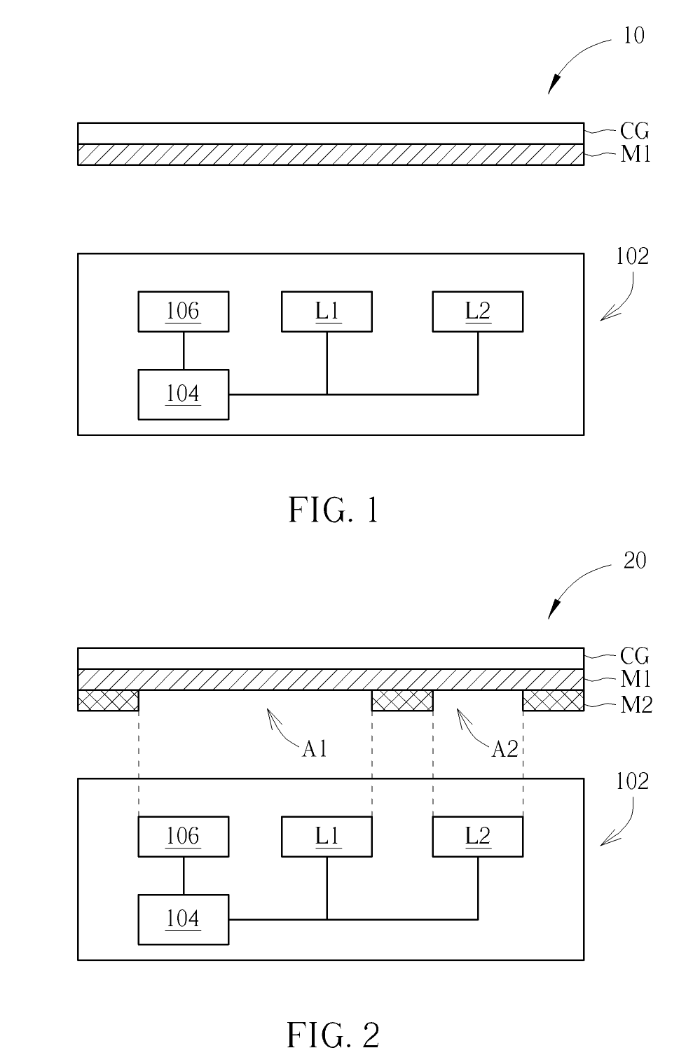

Please refer to FIG. 1, which is a schematic diagram of a proximity sensing module 10 according to an embodiment of the present invention. The proximity sensing module 10 includes a cover glass CG, a first masking layer M1 and a proximity sensor 102, wherein the proximity sensor 102 includes a control circuit 104, a light sensing element 106, a near-distance light-emitting element L1 and a far-distance light-emitting element L2. The proximity sensing module 10 may be applied on an electronic device with a touch function. The cover glass CG is utilized for protecting the proximity sensor 102, so as to prevent dust or artificial damages to the proximity sensor 102. The first masking layer M1 is coated on an inner surface of the cover glass CG, and the first masking layer M1 is a non-aperture masking layer. In an embodiment, the first masking layer M1 may be an ink layer, wherein a color of the ink layer may be white, red or other different colors, such that the color may be displayed on a touch panel of the electronic device, but not limited thereto. The proximity sensor 102 is utilized for sensing a distance between an object and the touch panel of the electronic device. The near-distance light-emitting element L1 and the far-distance light-emitting element L2 respectively emit a near-distance light source and a far-distance light source according to a control signal of the control circuit 104. And the light sensing element 106 is utilized for sensing the near-distance light source and the far-distance light source reflected by the object, so as to determine the distance between the proximity sensor 102 and the object according to light intensities of the reflected near-distance light source and the reflected far-distance light source. Notably, the light sensing element 106 and the near-distance light-emitting element L1 of the proximity sensing module 10 of the present invention exist a first distance, the light sensing element 106 and the far-distance light-emitting element L2 exist a second distance, and the second distance is greater than the first distance. Therefore, the light sensing element 106 of the present invention senses the different light intensities of the light sources generated by the near-distance light-emitting element L1 and the far-distance light-emitting element L2, so as to correctly determine the distance between the object and the electronic device even if the first masking layer M1 is the non-aperture mechanism.

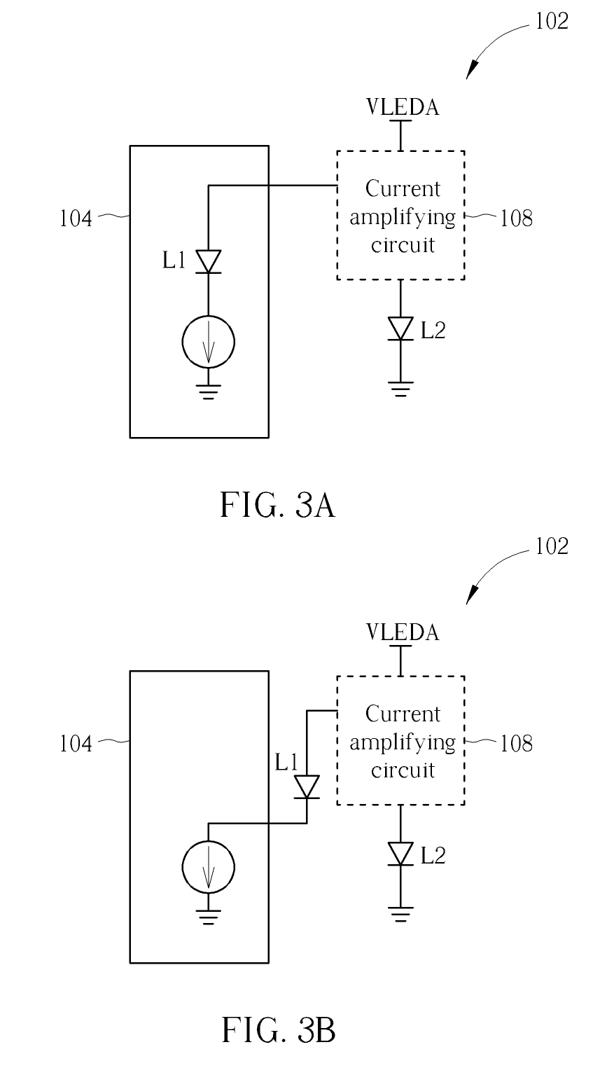

In details, please continue to refer to FIG. 2, which is a schematic diagram of a proximity sensing module 20 according to an embodiment of the present invention. For brevity, the same elements in FIG. 2 are denoted by the same symbols in FIG. 1. Different from FIG. 1, the proximity sensing module 20 of FIG. 2 further includes a second masking layer M2, which is coated on an inner surface of the first masking layer M1. In an embodiment, the second masking layer M2 may be an opaque coated layer, thus, the second masking layer M2 may be utilized for covering an inner circuit of the electronic device, so as to prevent a user from perceiving the inner circuit. In addition, the second masking layer M2 includes a first aperture A1 and a second aperture A2, such that the near-distance light-emitting element L1 emits the near-distance light source through the first aperture A1 and the cover glass CG, the far-distance light-emitting element L2 emits the far-distance light source through the second aperture A2 and the cover glass CG. Then, the light sensing element 106 of the proximity sensor 102 receives the near-distance light source and the far-distance light source reflected by the object through the first aperture A1. The near-distance light source has a first light intensity, and the far-distance light source has a second light intensity. In an embodiment, the first light intensity is smaller than the second light intensity, and the distance between the far-distance light-emitting element L2 and the light sensing element 106 is further than that between the near-distance light-emitting element L1 and the light sensing element 106. For example, the first distance between the near-distance light-emitting element L1 and the light sensing element 106 is 1 mm to 8 mm, the second distance between the far-distance light-emitting element L2 and the light sensing element 106 is 8 mm to 25 mm, but not limited thereto. Under the situation, since the first light intensity of the near-distance light-emitting element L1 is smaller, a crosstalk value sensed by the light sensing element 106 of the proximity sensor 102 is significantly decreased, and the far-distance light-emitting element L2 may detect the distance for a far-distance object, so as to determine the distance between the object and the electronic device. Moreover, in the embodiment, the second masking layer M2 is disposed to auxiliarily absorb the light source, which is emitted by the far-distance light-emitting element L2 and impenetrable to the cover glass CG, so as to reduce the light intensity of the light source impenetrable to the cover glass CG when arriving the light sensing element 106, and to reduce the crosstalk value sensed by the light sensing element 106.

For example, under the structure of the non-aperture mechanism, a proximity sensing module of a conventional technology only has a single light-emitting element, which is an infrared light-emitting diode (IR LED) with a current of 100 mA. In this situation, sensing results of light sensing values of the object and the proximity sensing module with the single light-emitting element are shown in Table 1.

TABLE 1

| | Light sensing |
|---|---|
| Object | value |
| None | 12,000 |
| gray card with distance of | 12,005 |
| 2 cm | |
| gray card with distance of | 12,000 |
| 3 cm | |
| black card with distance of | 20,000 |
| 0 cm | |

When no object exists and the light source is emitted by the light-emitting element, the light sensing value, i.e. the crosstalk value, sensed by a light sensing element is 12000; when the object is a gray card with a distance of 2 cm, the light sensing value sensed by the light sensing element is 12005, which is close to the crosstalk value sensed by the light sensing element; and when the object is the gray card with the distance of 3 cm (or above), the light sensing value sensed by the light sensing element is 12000, which is indistinguishable from the crosstalk value sensed by the light sensing element. In the situation, since a transmittance rate of the light source emitted from the light-emitting element is too low under the non-aperture mechanism, such that the light sensing element receives a large amount of light source emitted from the light-emitting element and impenetrable to the cover glass, and the crosstalk value is increased consequently, which results in a deficiency of sensitivity of the light sensing element. Therefore, the conventional proximity sensing module cannot correctly detect the distance between the object and the electronic device under the non-aperture mechanism.

In comparison, in an embodiment of the present invention, the proximity sensing module 20 is provided under the non-aperture mechanism. When the near-distance light-emitting element L1 and the far-distance light-emitting element L2 respectively have the same IR LED with the same power, the distance between the near-distance light-emitting element L1 and the light sensing element 106 is 1 mm, the distance between the far-distance light-emitting element L2 and the light sensing element 106 is 13 mm, and currents of the near-distance light-emitting element L1 and the far-distance light-emitting element L2 are respectively 25 mA and 150 mA, the sensing results of light sensing values of the object and the proximity sensing module 20 are shown in Table 2.

TABLE 2

| | Light sensing |
|---|---|
| Object | value |
| None | 2,250 |
| gray card with distance of | 2,495 |
| 3 cm | |
| gray card with distance of | 2,400 |
| 4 cm | |
| black card with distance of | 2,520 |
| 0 cm | |

When no object exists, the near-distance light source and the far-distance light source are respectively emitted from the near-distance light-emitting element L1 and the far-distance light-emitting element L2, the light sensing value, i.e. the crosstalk value, sensed by a light sensing element 106 is 2250; when the object is the gray card with the distance of 3 cm, the light sensing value sensed by the light sensing element 106 is 2495; when the object is the gray card with the distance of 4 cm, the light sensing value sensed by the light sensing element 106 is 2520; and when the object is the black card with the distance of 0 cm, the light sensing value sensed by the light sensing element 106 is 2520, which is larger than the light sensing value when the object is the gray card with the distance of 3 cm. Therefore, under the non-aperture mechanism, the proximity sensing module 20 of the present invention significantly reduces the crosstalk value when no object exists, so as to improve the sensitivity of the light sensing element 106 and correctly detect the distance between the object and the electronic device.

Notably, in the above embodiment, since current intensities of the near-distance light-emitting element L1 and the far-distance light-emitting element L2 are different, wherein the current intensities are respectively 5-25 mA and 100-200 mA, such that the light intensities of the near-distance light source and the far-distance light source are different. However, the power and the current value of the near-distance light-emitting element L1 and the far-distance light-emitting element L2 are not limited thereto, other kinds of light-emitting elements capable of implementing configurations of emitting different light intensities are all suitable for the present invention. That is, the proximity sensing module 20 of the present invention detects the object at a nearer distance by the near-distance light source with a weaker light intensity, so as to conform to the characteristics of the black card with the distance of 0 cm. As such, when the proximity sensing module 20 is applied on the electronic device, the light sensing value of the proximity sensing module 20 will not be too close to the crosstalk value when a black hair or a black object approaches to the electronic device. On the other hand, the proximity sensing module 20 detects the object at a further distance by the far-distance light source with a stronger light intensity. Moreover, as can be known from Table 1 and Table 2, the proximity sensing module 20 of the present invention obviously reduces the sensed crosstalk value when no object exists. Therefore, the proximity sensing module 20 of the present invention is free from a further mechanism for crosstalk cancellation and may correctly detect the distance between the object and the electronic device under the non-aperture mechanism.

Notably, if the distance between the far-distance light-emitting element L2 and the light sensing element 106 is increased to 21 mm in the above embodiment, the sensing results of the light sensing values of the object and the proximity sensing module 20 are shown in Table 3.

TABLE 3

| | Light sensing |
|---|---|
| Object | value |
| None | 1,100 |
| gray card with distance | 1,340 |
| of 3 cm | |
| gray card with distance | 1,230 |
| of 4 cm | |
| black card with distance | 1,265 |
| of 0 cm | |

When no object exists, the near-distance light source and the far-distance light source are emitted from the near-distance light-emitting element L1 and the far-distance light-emitting element L2 respectively, the light sensing value, i.e. the crosstalk value, sensed by a light sensing element 106 is 1100; when the object is the gray card with the distance of 3 cm, the light sensing value sensed by the light sensing element 106 is 1340; when the object is the gray card with the distance of 4 cm, the light sensing value sensed by the light sensing element 106 is 1230; when the object is the black card with the distance of 0 cm, the light sensing value sensed by the light sensing element 106 is 1265, which is larger than the light sensing value when the object is the gray card with the distance of 4 cm. Therefore, the crosstalk value when no object exists is further reduced in this embodiment, and since the light sensing value when the object is the black card with the distance of 0 cm is larger than that of the gray card with the distance of 4 cm, the sensitivity requirement for the light sensing element 106 when object is the black card with the distance of 0 cm is still satisfied, so as to correctly detect the distance between the object and the electronic device.

The proximity sensing modules 10 and 20 determine the distance between the object and the electronic device by sensing the first light intensity and the second light intensity of the reflected near-distance light source and the reflected far-distance light source. Therefore, in an embodiment, when the near-distance light-emitting element L1 and the far-distance light-emitting element L2 are the same IR LEDs with the same power, the proximity sensor 102 of the present invention may control the currents flowing through the near-distance light-emitting element L1 and the far-distance light-emitting element L2 according to the control signal generated by the control circuit 104. Moreover, the present invention may be implemented by a single-channel current source or a two-channel current source to control the currents of the near-distance light-emitting element L1 and the far-distance light-emitting element L2, so as to drive the near-distance light-emitting element L1 and the far-distance light-emitting element L2 with different current values, and consequently the near-distance light-emitting element L1 and the far-distance light-emitting element L2 have different light intensities.

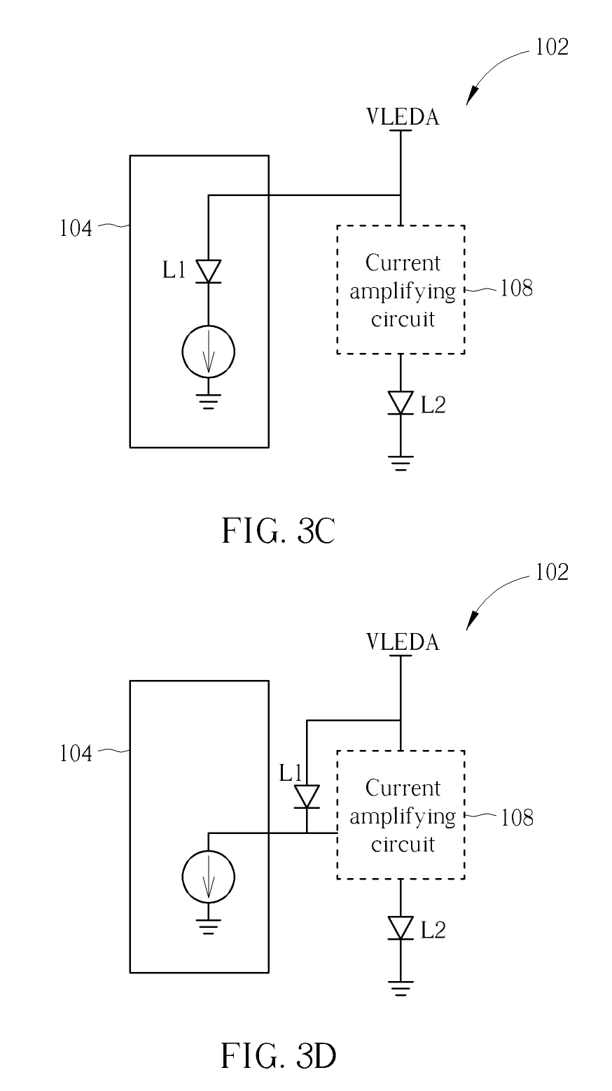

As to the embodiment of driving the near-distance light-emitting element L1 and the far-distance light-emitting element L2 with different current values, please further refer to FIGS. 3A-3D, which are circuit diagrams of the proximity sensor 102 according to embodiments of the present invention. As shown in FIGS. 3A-3D, when the proximity sensor 102 is implemented by the single-channel current source, the proximity sensor 102 may further include a current amplifying circuit 108 for amplifying the current. Therefore, when the near-distance light-emitting element L1 is disposed inside or outside of the control circuit 104, the proximity sensor 102 drives the near-distance light-emitting element L1 and the far-distance light-emitting element L2 with one current source and the current amplifying circuit 108, such that the near-distance light-emitting element L1 and the far-distance light-emitting element L2 respectively emit the light sources with different light intensities.

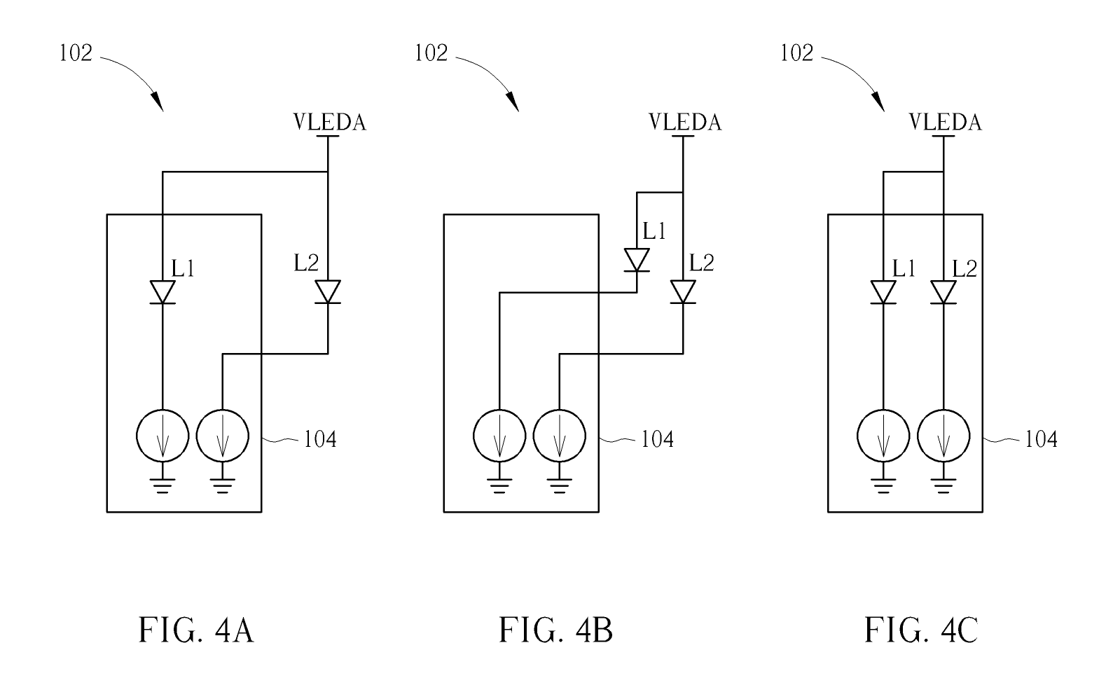

In another embodiment, please continue to refer to FIGS. 4A-4C. As shown in FIGS. 4A-4C, when the proximity sensor 102 is implemented by the two-channel current source, which is capable of driving the near-distance light-emitting element L1 and the far-distance light-emitting element L2 via the same voltage source VLEDA, so as to emit the light sources with different light intensities by two current sources, which is free from the current amplifier to drive the light-emitting element. In other words, all kinds of circuits may be utilized on the proximity sensor 102 of the present invention to control the current values of the near-distance light-emitting element L1 and the far-distance light-emitting element L2, so as to generate the light sources with different light intensities.

As can be known from the above, each embodiment of the present invention utilizes the light intensities of the light sources generated by different light-emitting elements to perform a distance sensing function under the non-aperture mechanism. Notably, the embodiments stated above are to illustrate the concept of the present invention, those skilled in the art may make proper modifications to the present invention according to different system requirements, and not limited thereto. For example, different powers, dimensions, models of the near-distance light-emitting element L1 and the far-distance light-emitting element L2 may be adopted, in this way, different current is not needed to drive the light-emitting elements, and the light sources with different light intensities are generated. Or, adding masks to change the light intensity and adjusting dimensions of the first aperture A1 and the second aperture A2 of the second masking layer M2 may change the light intensities of the light sources generated by the near-distance light-emitting element L1 and the far-distance light-emitting element L2. Moreover, materials of the first masking layer M1 and the second masking layer M2 of the proximity sensing module may be modified according to requirements of the electronic device or the user, which are not limited thereto, and all belong to the scope of the present invention.

In summary, the proximity sensing module of the present invention uses the light sensing element to sense the light sources reflected by the object and having different light intensities, to determine the distance with the object. Therefore, the proximity sensing module of the present invention may be applied on the electronic device when the surface is the non-aperture mechanism, which not only improves the appearance of the electronic device, but also provides the distance sensing function.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A proximity sensor for a non-aperture mechanism, comprising:
a control circuit for generating a control signal;
a first light-emitting element coupled to the control circuit, for emitting a first light source according to the control signal of the control circuit;
a second light-emitting element coupled to the control circuit, for emitting a second light source according to the control signal of the control circuit; and
alight sensing element coupled to the control circuit, for sensing the first light source and the second light source reflected by an object, and determining a distance between the proximity sensor and the object according to light intensities of the reflected first light source and the reflected sensed second light source;
wherein the light sensing element and the first light-emitting element have a first distance therebetween, the light sensing element and the second light-emitting element have a second distance therebetween, and the second distance is greater than the first distance.

2. The proximity sensor of claim 1, wherein a first light intensity of the first light source is smaller than a second light intensity of the second light source.

3. The proximity sensor of claim 2, wherein the proximity sensor detects a near-distance object according to the first light intensity of the first light source, and the proximity sensor detects a far-distance object according to the second light intensity of the second light source.

4. The proximity sensor of claim 2, wherein the first light-emitting element and the second light-emitting element are light-emitting elements with different power.

5. The proximity sensor of claim 2, wherein the control signal is related to a current value of the first light-emitting element and the second light-emitting element.

6. The proximity sensor of claim 1, wherein the first light-emitting element and the second light-emitting element are infrared light-emitting diodes.

7. The proximity sensor of claim 1, wherein the first distance between the first light-emitting element and the light sensing element is 1 mm to 8 mm, and the second distance between the second light-emitting element and the light sensing element is 8 mm to 25 mm.

8. A proximity sensing module, comprising:
a cover glass;
a first masking layer coated on an inner surface of the cover glass, wherein the first masking layer is a non-aperture masking layer; and
a proximity sensor for determining a distance with an object by emitting light sources and receiving the reflected light sources, wherein the proximity sensor comprises:
a control circuit for generating a control signal;
a first light-emitting element coupled to the control circuit, for emitting a first light source according to the control signal of the control circuit;
a second light-emitting element coupled to the control circuit, for emitting a second light source according to the control signal of the control circuit; and
a light sensing element coupled to the control circuit, for sensing the first light source and the second light source reflected by the object, and determining the distance between the proximity sensor and the object according to light intensities of the reflected first light source and the reflected sensed second light source;
wherein the light sensing element and the first light-emitting element have a first distance therebetween, the light sensing element and the second light-emitting element have a second distance therebetween, and the second distance is greater than the first distance.

9. The proximity sensing module of claim 8, wherein a first light intensity of the first light source is smaller than a second light intensity of the second light source.

10. The proximity sensing module of claim 9, wherein the proximity sensor detects a near-distance object according to the first light intensity of the first light source, and the proximity sensor detects a far-distance object according to the second light intensity of the second light source.

11. The proximity sensing module of claim 9, wherein the first light-emitting element and the second light-emitting element are light-emitting elements with different power.

12. The proximity sensing module of claim 9, wherein the control signal is related to a current value of the first light-emitting element and the second light-emitting element.

13. The proximity sensing module of claim 9, wherein the first light-emitting element and the second light-emitting element are infrared light-emitting diodes.

14. The proximity sensing module of claim 8, wherein the first masking layer is an ink layer.

15. The proximity sensing module of claim 8, wherein the first distance between the first light-emitting element and the light sensing element is 1 mm to 8 mm, and the second distance between the second light-emitting element and the light sensing element is 8 mm to 25 mm.

16. The proximity sensing module of claim 8, further comprising:
a second masking layer coated on an inner surface of the first masking layer, wherein the second masking layer has a plurality of apertures.

17. The proximity sensing module of claim 16, wherein the second masking layer is an opaque coated layer.

18. The proximity sensing module of claim 16, wherein the first light-emitting element emits the first light source through a first aperture of the plurality of apertures, and the second light-emitting element emits the second light source through a second aperture of the plurality of apertures.

19. The proximity sensing module of claim 16, wherein the light sensing element of the proximity sensor receives the reflected light sources through the first aperture of the plurality of apertures.
